(19) United States
(12) Patent Application Publication
(10) Pub. No.: US 2025/0161840 A1
(43) Pub. Date: May 22, 2025

(54) FLUID FILTRATION FOR SEMICONDUCTOR PROCESSING

(71) Applicant: Taiwan Semiconductor Manufacturing Company Limited, Hsin-Chu (TW)

(72) Inventors: Chia Pao CHANG, Tainan City (TW); Ke-Chang LU, Taichung City (TW); Yi Xian LI, Taoyuan City (TW)

(21) Appl. No.: 18/513,912

(22) Filed: Nov. 20, 2023

(51) Int. Cl. B01D 15/18; B01D 15/36; B01D 15/38; B01D 61/58; G03F 7/00; G03F 7/30; H01L 21/67

(52) U.S. Cl. CPC B01D 15/1871; B01D 15/361; B01D 15/38; B01D 61/58; G03F 7/30; G03F 7/70916; H01L 21/67017; B01D 2313/16; B01D 2313/60; B01D 2313/903

(57) ABSTRACT

A fluid filtration system for a semiconductor processing station is provided. The fluid filtration system includes a first filter configured to filter metal ions from a first fluid to produce a first filtered fluid. The fluid filtration system includes a second filter configured to filter particles from the first filtered fluid to produce a second filtered fluid. The fluid filtration system includes a conduit configured to conduct the second filtered fluid to the semiconductor processing station.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer. The semiconductor wafer is transferred to stations used to perform the one or more semiconductor fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic view of a fluid filtration system, in accordance with some embodiments.

FIG. 1B illustrates a schematic view of a fluid filtration system supplying filtered fluid to a semiconductor processing station, in accordance with some embodiments.

FIG. 2A illustrates a perspective view of a first filter cabinet, in accordance with some embodiments.

FIG. 2B illustrates a perspective view of a first filter support assembly, in accordance with some embodiments.

FIG. 2C illustrates a perspective view of a first filter cabinet, in accordance with some embodiments.

FIG. 2D illustrates a perspective view of a first filter cabinet, in accordance with some embodiments.

FIG. 2E illustrates a perspective view of a first filter cabinet, in accordance with some embodiments.

FIG. 2F illustrates a perspective view of a supplemental filter support assembly, in accordance with some embodiments.

FIG. 2G illustrates a perspective view of a supplemental filter support assembly, in accordance with some embodiments.

FIG. 2H illustrates a perspective view of a first filter cabinet, in accordance with some embodiments.

FIG. 3 illustrates aspects of a fluid filtration system, in accordance with some embodiments.

FIG. 4A illustrates a perspective view of a second filter cabinet, in accordance with some embodiments.

FIG. 4B illustrates a perspective view of a second filter cabinet, in accordance with some embodiments.

FIG. 5A illustrates a perspective view of a third filter cabinet, in accordance with some embodiments.

FIG. 5B illustrates a perspective view of a third filter cabinet, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

Semiconductor wafers are subjected to various processes in various processing stations during the fabrication of semiconductor devices. In some embodiments, a semiconductor processing station uses a filtered fluid to perform a first semiconductor fabrication process on a first semiconductor wafer. In accordance some embodiments of the present disclosure, the filtered fluid is provided by a fluid filtration system comprising a metal ion filter that filters metal ions from the filtered fluid. In some embodiments, filtering the filtered fluid using the metal ion filter provides for reduced metal ions in the filtered fluid. In some embodiments, the reduction in metal ions provides for reduced wafer defects in the first semiconductor wafer, such as at least one of a reduction in metal cones on the first semiconductor wafer or a reduction in other types of defects in the first semiconductor wafer.

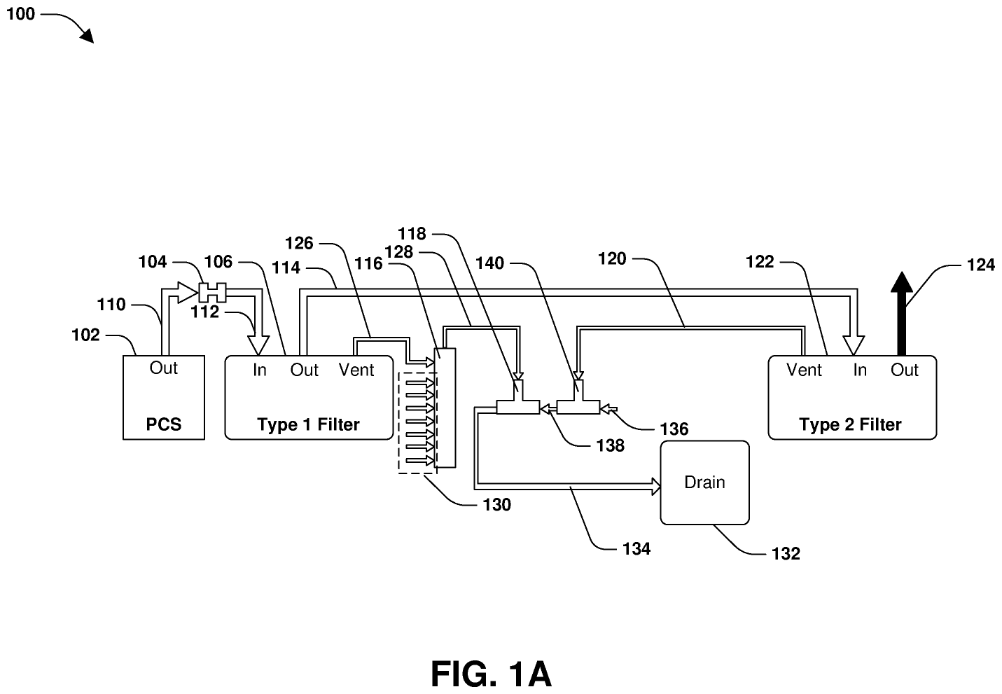

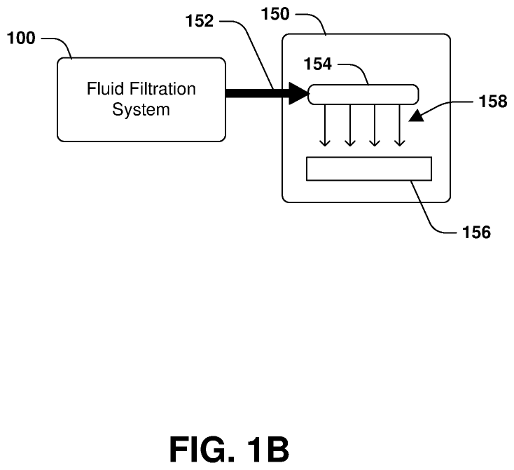

FIGS. 1A-1B illustrate aspects of a fluid filtration system 100, according to some embodiments. FIG. 1A illustrates a schematic view of the fluid filtration system 100, according to some embodiments. In some embodiments, the fluid filtration system is configured to filter a fluid and supply a filtered fluid to one or more semiconductor processing stations comprising at least one of a first semiconductor processing station 150 (shown in FIG. 1B), a second semiconductor processing station (not shown), etc. In some embodiments, the filtered fluid is used by a semiconductor processing station of the one or more semiconductor processing stations to perform a semiconductor fabrication process on one or more semiconductor wafers.

In some embodiments, the fluid filtration system 100 comprises at least one of a fluid control system 102, a first filter 106, a second filter 122, a drain manifold 116, or one or more other components. In some embodiments, the fluid control system 102 comprises a pump control system (PCS). In some embodiments, the fluid control system 102 comprises one or more pumps configured to pump a first fluid from a fluid source, such as a reservoir comprising the first fluid, to the first filter 106. In some embodiments, the first fluid flows from the fluid control system 102 to the first filter 106 via at least one of a conduit 110, a fitting 104, or a conduit 112. In some embodiments, the fitting 104 connects the conduit 110 to the conduit 112 to establish a flow path between the conduit 110 and the conduit 112. In some embodiments, the fitting 104 comprises at least one of (i) a flow regulation device to regulate flow from the fluid control system 102 to the first filter 106, (ii) a sensor to measure a flow rate of the first fluid to the first filter 106, or (iii) one or more other components. In some embodiments, a first side of the fitting 104 is adapted to a first size and/or shape of the conduit 110 and a second side of the fitting 104 is adapted to a second size and/or shape of the conduit 112. In some embodiments, the conduit 112 is connected to an input port (“In” in FIG. 1A) of the first filter 106. In some embodiments, the first fluid flows into the first filter 106 through the input port of the first filter 106.

In some embodiments, the first filter 106 is configured to filter impurities from the first fluid to produce a first filtered fluid. In some embodiments, the first filter 106 comprises a purifier filter. In some embodiments, the first filter 106 is configured to filter metal ions from the first fluid to produce the first filtered fluid. In some embodiments, the first filter 106 comprises at least one of ultra-high molecular weight polyethylene (UPE) or other suitable material. In some embodiments, the metal ions comprise at least one of iron (Fe) ions or one or more other types of metal ions.

In some embodiments, the first filter 106 filters the metal ions via chemical chelation. In some embodiments, the first filter 106 comprises chelating agents used to filter the metal ions. In some embodiments, the first filter 106 is treated with the chelating agents. In some embodiments, while the first fluid flows through the first filter 106, a chelating agent combines with a metal ion in the first fluid to form a metal chelate. In some embodiments, the metal chelate is filtered from the first fluid to produce the first filtered fluid. In some embodiments, the metal chelate is filtered using a first porous structure, such as a first membrane. In some embodiments, the first filter 106 comprises the first porous structure. In some embodiments, the first porous structure separates the metal chelate from the first fluid to produce the first filtered fluid. In some embodiments, the first filter 106 comprises adsorbing agents used to filter the metal ions. In some embodiments, the first filter 106 is treated with the adsorbing agents. In some embodiments, while the first fluid flows through the first filter 106, an adsorbing agent adsorbs a metal ion in the first fluid to separate the metal chelate from the first fluid to produce the first filtered fluid. In some embodiments, the first filter 106 is configured to filter the metal ions via ion exchange. In some embodiments, the first filter 106 comprises an ion exchange filter that separates the metal ions from the first fluid to produce the first filtered fluid. Other means for filtering the metal ions using the first filter 106 are within the scope of the present disclosure.

A first filter size of the first filter 106 is between about 20 nanometers to about 100 nanometers (and/or the first filter size is about 50 nanometers). Other values of the first filter size are within the scope of the present disclosure. In some embodiments, the first filter size corresponds to a first pore size of the first porous structure.

In some embodiments, the first filtered fluid is output via an output port (“Out” in FIG. 1A) of the first filter 106. In some embodiments, the first filtered fluid is conducted from the first filter 106 to the second filter 122 via a conduit 114. In some embodiments, the conduit 114 is connected to an input port (“In” in FIG. 1A) of the second filter 122. In some embodiments, the first filtered fluid flows into the second filter 122 through the input port of the second filter 122.

In some embodiments, the second filter 122 is configured to filter impurities from the first filtered fluid to produce a second filtered fluid. In some embodiments, the second filter 122 is configured to filter particles from the first filtered fluid to produce the second filtered fluid. In some embodiments, the second filter 122 comprises a second porous structure, such as a second membrane. In some embodiments, a particle size of particles filtered by the second filter 122 is a function of a second filter size of the second filter 122. In some embodiments, the second filter size corresponds to a second pore size of the second porous structure. In some embodiments, the first filter 106 comprises the first porous structure.

In some embodiments, the second filtered fluid is output via an output port (“Out” in FIG. 1A) of the second filter 122. In some embodiments, the second filtered fluid is conducted from the second filter 122 to the first semiconductor processing station 150 via a conduit 124.

In some embodiments, the first filter 106 is a type 1 filter. In some embodiments, as used in the present disclosure, a type 1 filter is a filter that at least one of (i) filters impurities, such as metal ions, from a fluid using one or more of the techniques provided herein with respect to the first filter 106, or (ii) has one or more of the features, dimensions, interrelationships with other elements, etc. provided herein with respect to the first filter 106.

In some embodiments, the second filter 122 is a type 2 filter. In some embodiments, as used in the present disclosure, a type 2 filter is a filter that filters impurities, such as particles, from a fluid using one or more of the techniques provided herein with respect to the second filter 122.

In some embodiments, a first filter flushing process is performed to flush the first filter 106. In some embodiments, the first filter flushing process removes impurities from the first filter 106. In some embodiments, the impurities comprise metal ions previously extracted from fluid filtered by the first filter 106. In some embodiments, during the first filter flushing process, the impurities exit the first filter 106 through a vent port (“Vent” in FIG. 1A) of the first filter 106. In some embodiments, when the first fluid flows through the first filter 106 to produce the first filtered fluid, the vent port of the first filter 106 is closed to block flow through the vent port of the first filter 106. In some embodiments, during the first filter flushing process, the vent port of the first filter 106 is open to allow flow through the vent port. In some embodiments, during the first filter flushing process, a first impurity fluid comprising impurities exits the first filter 106 through the vent port of the first filter 106 and the first impurity fluid flows through one or more first components to a drain 132. In some embodiments, the one or more first components comprise at least one of a conduit 126, the drain manifold 116, a conduit 128, a tee fitting 118, or a conduit 134.

In some embodiments, the drain manifold 116 is connected to the first filter 106 via the conduit 126, and is connected to a set of filters (not shown) via a set of conduits 130. In some embodiments, each conduit of one, some, or all of the set of conduits 130 is connected to a vent port of a filter of the set of filters. In some embodiments, during one or more filter flushing processes of one or more respective filters of the set of filters, impurity fluid flows through each conduit of one, some, or all of the set of conduits 130 into the drain manifold 116, wherein the impurity fluid flows through the drain manifold 116 into the conduit 128, and the impurity fluid is conducted to the drain 132 via at least one of the conduit 128, the tee fitting 118, or the conduit 134.

In some embodiments, a second filter flushing process is performed to flush the second filter 122. In some embodiments, the second filter flushing process removes impurities from the second filter 122. In some embodiments, the impurities comprise particles previously extracted from fluid filtered by the second filter 122. In some embodiments, during the second filter flushing process, the impurities exit the second filter 122 through a vent port (“Vent” in FIG. 1A) of the second filter 122. In some embodiments, when the first filtered fluid flows through the second filter 122 to produce the second filtered fluid, the vent port of the second filter 122 is closed to block flow through the vent port of the second filter 122. In some embodiments, during the second filter flushing process, the vent port of the second filter 122 is open to allow flow through the vent port. In some embodiments, during the second filter flushing process, a second impurity fluid comprising impurities exits the second filter 122 through the vent port of the second filter 122 and the second impurity fluid flows through one or more fifth components to the drain 132. In some embodiments, the one or more fifth components comprise at least one of a conduit 120, a tee fitting 140, a conduit 138, the tee fitting 118, or the conduit 134.

In some embodiments, the tee fitting 140 is connected to the second filter 122 via the conduit 120, and is connected to one or more other filters (not shown) via one or more conduits 136. In some embodiments, each conduit of one, some, or all of the one or more conduits 136 is connected to a vent port of a filter. Embodiments are contemplated in which the fluid filtration system 100 comprises a second drain manifold to facilitate draining impurity fluid from the second filter 122 and/or the one or more other filters using one or more of the techniques provided herein with respect to the drain manifold 116.

FIG. 1B illustrates the fluid filtration system 100 supplying the second filtered fluid to the first semiconductor processing station 150, in accordance with some embodiments. In some embodiments, the first semiconductor processing station 150 is configured to perform a semiconductor fabrication process on a first semiconductor wafer 156. In some embodiments, the first semiconductor processing station 150 performs the semiconductor fabrication process when the first semiconductor wafer 156 is in a processing chamber of the first semiconductor processing station 150. In some embodiments, the fluid filtration system 100 comprises a conduit 152 configured to conduct the second filtered fluid to the first semiconductor processing station 150. In some embodiments, the conduit 152 comprises at least one of the conduit 124 (shown in FIG. 1A) or one or more other conduits. In some embodiments, the first semiconductor processing station 150 comprises a fluid dispensing component 154 configured to dispense the second filtered fluid. In some embodiments, during the semiconductor fabrication process, the fluid dispensing component 154 dispenses filtered fluid 158 (received from the conduit 152) onto the first semiconductor wafer 156 to treat the first semiconductor wafer 156. In some embodiments, the fluid dispensing component comprises at least one of (i) a nozzle, (ii) a showerhead, (iii) a puddle, (iv) a structure with one or more fluid paths which conduct the filtered fluid 158 from the conduit 152 to one or more outlets (not shown) of the fluid dispensing component, wherein the filtered fluid 158 exits the one or more outlets to be dispensed onto the first semiconductor wafer 156, or (v) other type of structure.

In some embodiments, the first semiconductor processing station 150 comprises lithography equipment. In some embodiments, the semiconductor fabrication process comprises a photomask development process performed to develop a photomask on the first semiconductor wafer 156 using the filtered fluid 158. In some embodiments, the filtered fluid 158 comprises a developer. In some embodiments, the developer comprises a developer liquid, such as a developer solution. In some embodiments, the fluid dispensing component 154 is configured to dispense the developer onto a photoresist (not shown) of the first semiconductor wafer 156 to develop the photomask. In some embodiments, the developer at least one of dissolves or washes away one or more regions of the photoresist of the first semiconductor wafer 156 to form the photomask from the photoresist. The photoresist comprises a light-sensitive material, where properties, such as solubility, of the photoresist are affected by light. The photoresist is a negative photoresist or a positive photoresist. With respect to a negative photoresist, regions of the negative photoresist become insoluble when illuminated by a light source, such that application of the developer to the negative photoresist during the photomask development process removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of the developer during the photomask development process. Thus, a pattern formed in the positive photoresist is a positive image of opaque regions of the template, such as a mask, between the light source and the positive photoresist. In some embodiments, the lithography equipment comprises at least one of (i) extreme ultraviolet lithography (EUVL) equipment, wherein the semiconductor fabrication process comprises a EUVL process, (ii) immersion lithography equipment, wherein the semiconductor fabrication process comprises an immersion lithography process, or (iii) other suitable lithography equipment.

In some embodiments, the first semiconductor processing station 150 comprises etching equipment. In some embodiments, the semiconductor fabrication process comprises etching one or more parts of the first semiconductor wafer 156 using the filtered fluid 158, and the filtered fluid 158 comprises an etching fluid. In some embodiments, the semiconductor fabrication process comprises an etching process, such as a wet etching process, an immersion etching process, or other suitable etching process.

In some embodiments, the first semiconductor processing station 150 comprises rinsing equipment. In some embodiments, the semiconductor fabrication process comprises rinsing the first semiconductor wafer 156 using the filtered fluid 158, and the filtered fluid 158 comprises a rinsing liquid. In some embodiments, the rinsing liquid comprises at least one of de-ionized water or other suitable liquid.

In some embodiments, the first semiconductor processing station 150 comprises coating equipment. In some embodiments, the semiconductor fabrication process comprises coating the first semiconductor wafer 156 using the filtered fluid 158, and the filtered fluid 158 comprises coating liquid. In some embodiments, the coating liquid is coated onto a surface of the first semiconductor wafer 156 during the semiconductor fabrication process.

In some embodiments, the first semiconductor processing station 150 comprises reduced resist consumption (RRC) equipment. In some embodiments, the semiconductor fabrication process comprises a RRC process comprising dispensing the filtered fluid 158 onto the first semiconductor wafer 156 prior to a photolithography process on the first semiconductor wafer 156, and the filtered fluid 158 comprises a solvent, such as a RRC solvent. In some embodiments, applying the filtered fluid 158 to the first semiconductor wafer 156 in the RRC process reduces an amount of photoresist material used by the photolithography process performed after the RRC process, such as due, at least in part, to the filtered fluid 158 acting as a lubricant to reduce an amount of photoresist material necessary for the photolithography process.

Other examples of the first semiconductor processing station 150 and the semiconductor fabrication process are within the scope of the present disclosure. In some embodiments, the first semiconductor processing station 150 comprises at least one of (i) plating equipment, wherein the semiconductor fabrication process comprises a plating process performed on the first semiconductor wafer 156 using the filtered fluid 158, (ii) chemical vapor deposition (CVD) equipment, wherein the semiconductor fabrication process comprises a CVD process performed on the first semiconductor wafer 156 using the filtered fluid 158, (iii) physical vapor deposition (PVD) equipment, wherein the semiconductor fabrication process comprises a PVD process performed on the first semiconductor wafer 156 using the filtered fluid 158, (iv) cleaning equipment, such as a cleaning tool comprising a cleaning tank in which the first semiconductor wafer 156 is at least one of washed, cleaned, etc. using the filtered fluid 158, or (v) other suitable equipment.

Embodiments are contemplated in which (i) the first fluid is filtered by the second filter 122 (type 2 filter) to produce the first filtered fluid, (ii) the first filtered fluid is filtered by the first filter 106 (type 1 filter) to produce the second filtered fluid, and (iii) the second filtered fluid is conducted to the first semiconductor processing station 150. Other arrangements of the first filter 106, the second filter 122 and other components relative to each other in addition to those shown in and/or described with respect to FIG. 1A are contemplated, such as an embodiment where the first filter 106 and the second filter 122 are switched relative to each other in FIG. 1A, and/or other embodiments.

In some embodiments, using fluid filtered using the type 1 filter in the semiconductor fabrication process provides for reduced defects, such as metal cones, on the first semiconductor wafer 156, as compared to embodiments in which the semiconductor fabrication process uses fluid that is not filtered using the type 1 filter. In some embodiments, the second filtered fluid comprises tetramethylammonium hydroxide (TMAH) used as a photomask developer and/or etchant in the semiconductor fabrication process to at least one of develop a photomask on the first semiconductor wafer 156 or etch one or more portions of the first semiconductor wafer 156. In some embodiments, filtering the TMAH using the type 1 filter is associated with about a 52% reduction in metal cones on the first semiconductor wafer 156, as compared to embodiments in which the TMAH is not filtered using the type 1 filter.

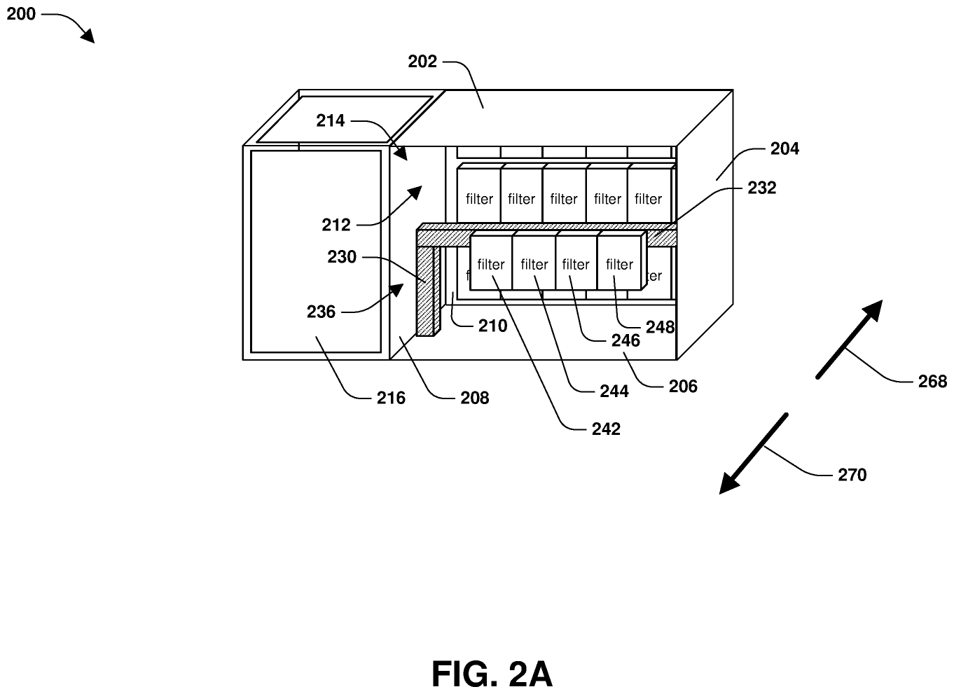

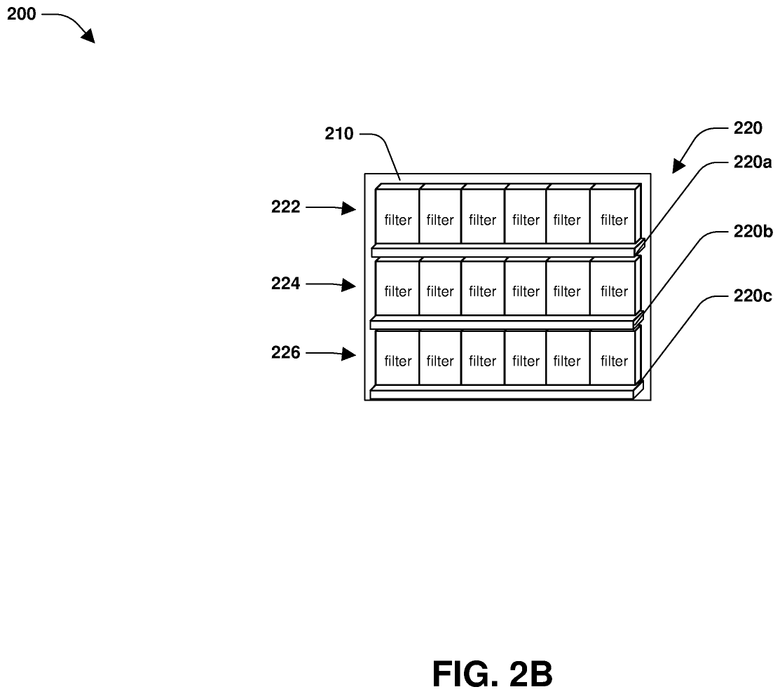

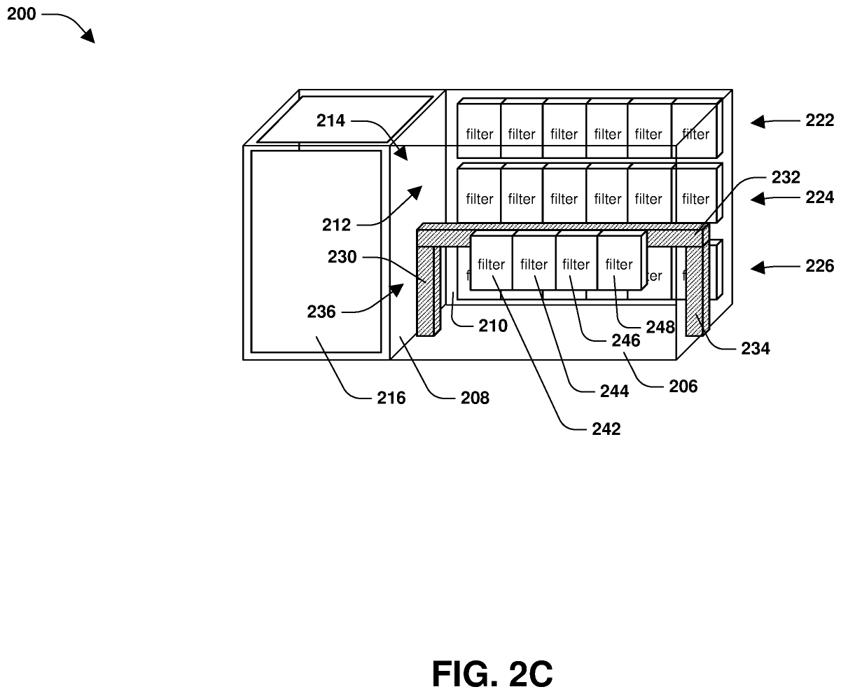

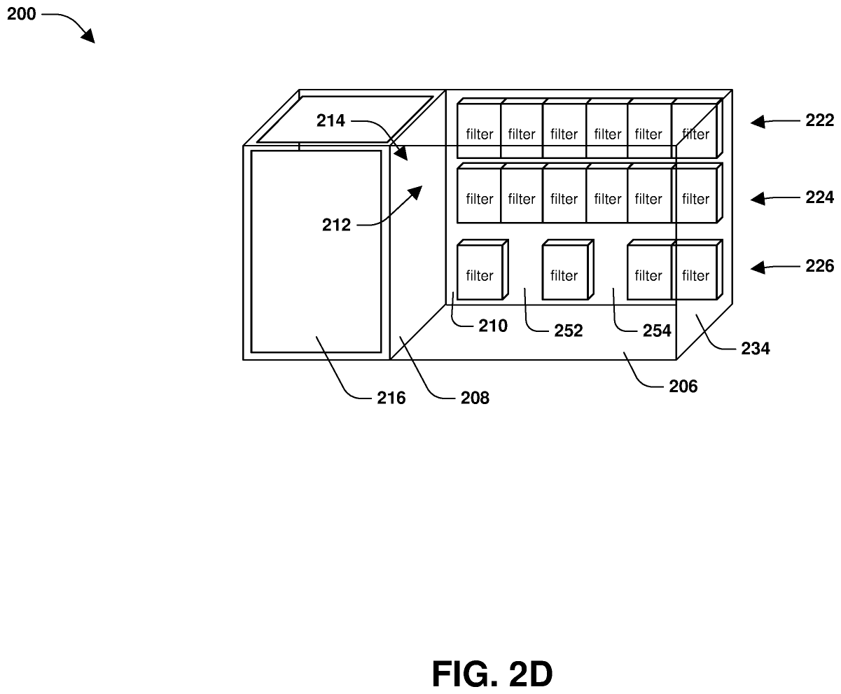

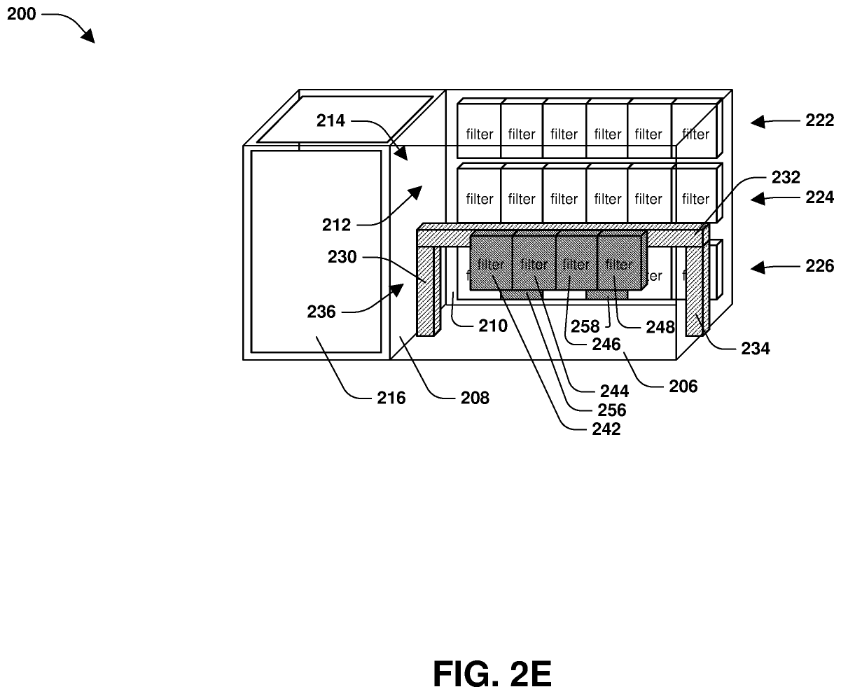

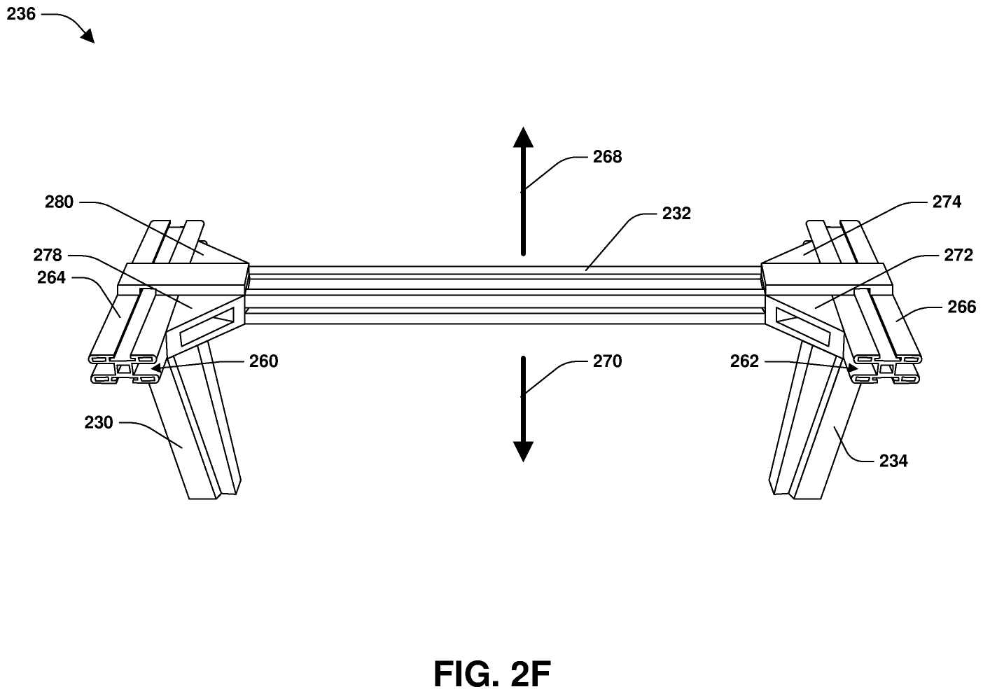

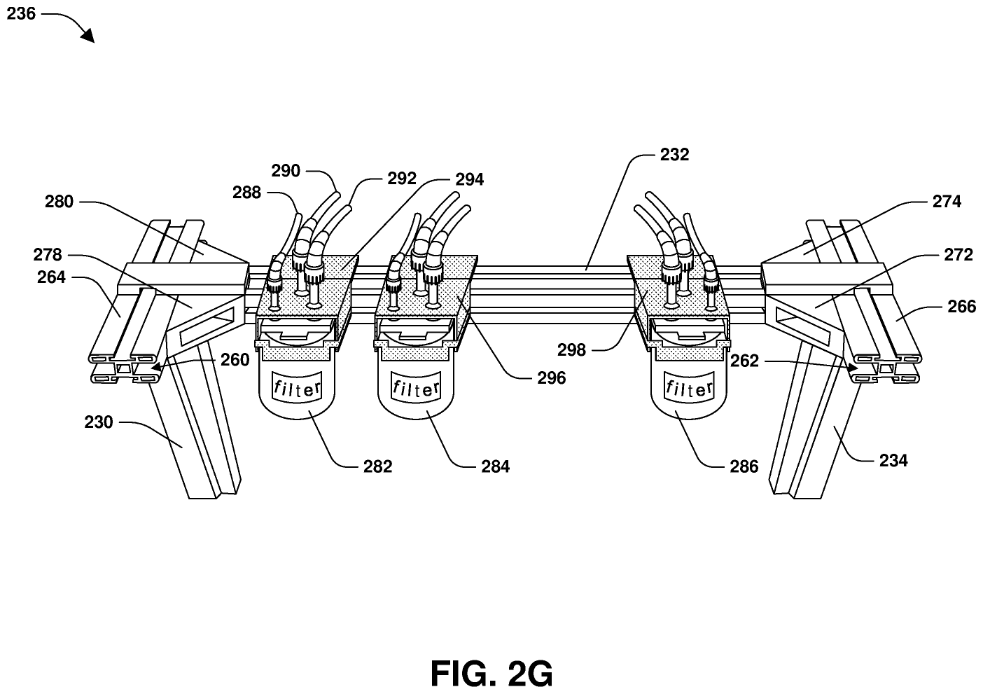

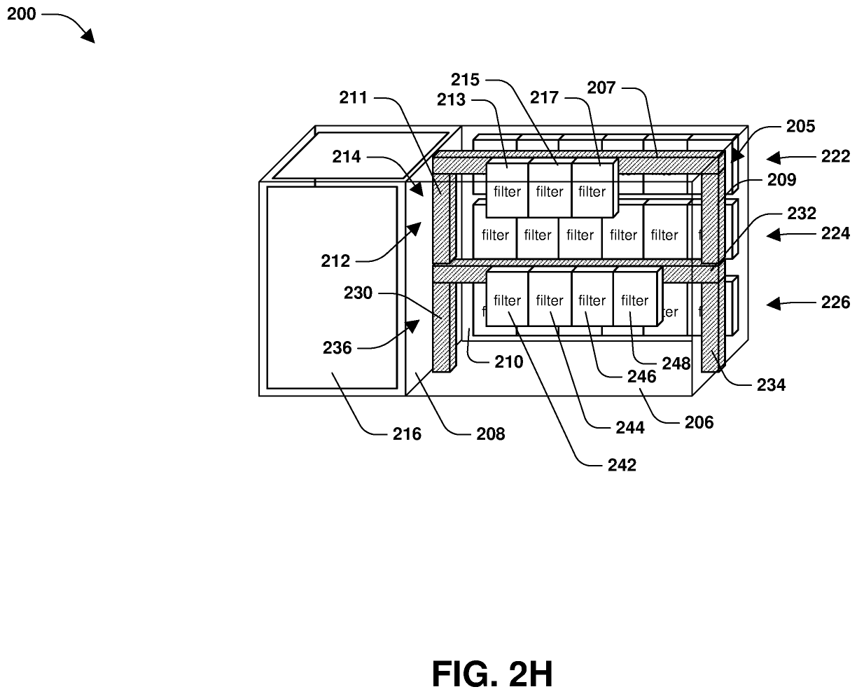

In some embodiments, the fluid filtration system 100 comprises a first filter cabinet 200. FIGS. 2A-2H illustrate aspects of the first filter cabinet 200, according to some embodiments. FIG. 2A illustrates a perspective view of the first filter cabinet 200, according to some embodiments. In some embodiments, the first filter cabinet 200 comprises at least one of a floor 206, a ceiling 202, or one or more walls to define a filter cabinet space 212. In some embodiments, the one or more walls comprise at least one of a first wall 204, a second wall 208 opposing the first wall 204, or a third wall 210. In some embodiments, the third wall 210 opposes an opening 214 to the filter cabinet space 212. In some embodiments, the first filter cabinet 200 comprises a door (not shown), fitted to the opening 214, to provide ingress and egress to the filter cabinet space 212. In some embodiments, when the door is open, the filter cabinet space 212 is exposed by the opening 214 to allow one or more maintenance operations to be performed. In some embodiments, the one or more maintenance operations comprise at least one of (i) inserting one or more filters into the filter cabinet space 212, (ii) removing one or more filters from the filter cabinet space 212, (iii) replacing one or more defective filters in the filter cabinet space 212 with one or more functioning filters, (iv) repairing one or more filters in the filter cabinet space 212, (v) flushing one or more filters in the filter cabinet space 212, (vi) servicing one or more filters in the filter cabinet space 212, or (vii) one or more other maintenance operations.

In some embodiments, the first filter cabinet 200 comprises an enclosure 216. In some embodiments, one or more second components (not shown) of the fluid filtration system 100 are disposed in the enclosure 216. In some embodiments, the one or more second components comprise at least one of one or more pumps, one or more components of the fluid control system 102, one or more conduits, etc.

In some embodiments, the first filter cabinet 200 comprises a first filter support assembly 220 (shown in FIG. 2B), in the filter cabinet space 212, configured to support a first plurality of filters. The first filter support assembly 220 comprises at least one of one or more metals or one or more other suitable materials. In some embodiments, the first filter support assembly 220 is at least one of proximal to, coupled to, or in contact with the third wall 210. In some embodiments, each filter of one, some, or all of the first plurality of filters is at least one of (i) in contact with the third wall, or (ii) coupled to the third wall 210, such as using the first filter support assembly 220. In some embodiments, the first filter support assembly 220 comprises at least one of one or more shelving units, one or more support beams, one or more brackets, or one or more other types of structures to support the first plurality of filters. For simplicity, the first filter support assembly 220 is not illustrated in the annexed figures except for FIG. 2B.

FIG. 2B illustrates the first filter support assembly 220 supporting the first plurality of filters, according to some embodiments in which the first filter support assembly 220 comprises shelving units. In some embodiments, the shelving units of the first filter support assembly 220 are coupled to the third wall 210. In some embodiments, the first plurality of filters comprises at least one of a first row of filters 222, a second row of filters 224, or a third row of filters 226. In some embodiments, at least one of (i) the first row of filters 222 are set upon and/or supported by a first shelving unit 220a of the first filter support assembly 220, (ii) the second row of filters 224 are set upon and/or supported by a second shelving unit 220b of the first filter support assembly 220, or (iii) the third row of filters 226 are set upon and/or supported by a third shelving unit 220c of the first filter support assembly 220. Other structures and/or configurations of the first filter support assembly 220 are within the scope of the present disclosure. In some embodiments, the first filter support assembly 220 comprises at least one of one or more support beams (not shown) or other type of structure to support filters of the first plurality of filters.

Embodiments are contemplated in which the first filter cabinet 200 does not comprise at least one of the ceiling 202, the floor 206, the first wall 204, the second wall 208, or the third wall 210. FIG. 2C illustrates the first filter cabinet 200 according to some embodiments in which the first filter cabinet 200 does not comprise at least one of the ceiling 202 or the first wall 204.

In some embodiments, the first filter cabinet 200 comprises a first supplemental filter support assembly 236, in the filter cabinet space 212, configured to support one or more first supplemental filters. The first supplemental filter support assembly 236 comprises at least one of one or more metals or one or more other suitable materials. In some embodiments, the first supplemental filter support assembly 236 is between the first filter support assembly 220 and the opening 214. In some embodiments, the first supplemental filter support assembly 236 is between the first plurality of filters and the opening 214. In some embodiments, the one or more first supplemental filters comprise at least one of a first supplemental filter 242, a second supplemental filter 244, a third supplemental filter 246, a fourth supplemental filter 248, or one or more other supplemental filters. Although four supplemental filters are shown, embodiments are contemplated in which any quantity of supplemental filters are supported by the first supplemental filter support assembly 236. In some embodiments, the first supplemental filter support assembly 236 comprises a first support beam 232 configured to support the one or more first supplemental filters. In some embodiments, the first supplemental filter support assembly 236 comprises at least one of a first support post 230 or a second support post 234. In some embodiments, the first support beam 232 is at least one of coupled to or supported by at least one of the first support post 230 or the second support post 234. In some embodiments, the first support post 230 is coupled to at least one of the second wall 208, the floor 206, or other structure. In some embodiments, the second support post 234 is coupled to at least one of the first wall 204, the floor 206, or other structure. In some embodiments, at least one of the first support beam 232, the first support post 230, or the second support post 234 comprises at least one of one or more brackets or other suitable structures.

In some embodiments, the first supplemental filter support assembly 236 is installed relative to the first filter cabinet 200 after the first filter support assembly 220 is installed relative to the first filter cabinet 200. In some embodiments, the first supplemental filter support assembly 236 is installed in the first filter cabinet 200 when a need arises to add supplemental filters relative to the first filter cabinet 200. FIG. 2D illustrates the first filter cabinet 200 without the first supplemental filter support assembly 236, according to some embodiments. In some embodiments, there is a need to add a set of supplemental filters relative to the first filter cabinet 200 to at least one of (i) increase at least one of a filtering rate of the fluid filtration system 100 or a quantity of filtered fluid output by the first filter cabinet 200, (ii) supply filtered fluid to one or more additional semiconductor processing stations using the set of supplemental filters, or (iii) add one or more supplemental filters, such as the type 1 filter, to the fluid filtration system 100 to provide for increased and/or improved filtering of fluid supplied to a semiconductor processing station such as the first semiconductor processing station 150.

In some embodiments, it is desirable to retrofit one or more supplemental types of filters, such as the type 1 filter, to the fluid filtration system 100. In some embodiments, prior to retrofitting the type 1 filter to the fluid filtration system 100, the fluid filtration system 100 at least one of (i) does not use the type 1 filter to filter fluid supplied to the first semiconductor processing station 150, or (ii) only uses the type 2 filter to filter the fluid supplied to the first semiconductor processing station 150.

In some embodiments, the first filter cabinet 200 has one or more unoccupied filter locations, such a first filter location 252 and a second filter location 254 relative to the third row of filters 226. In some embodiments, the set of supplemental filters to be added relative to the first filter cabinet 200 include more filters than can be accommodated by the one or more unoccupied filter locations. In some systems, a second filter cabinet is required to be installed in order to accommodate at least some of the set of supplemental filters. However, in accordance with some embodiments of the present disclosure, the set of supplemental filters can be added relative to the first filter cabinet 200 by installing the first supplemental filter support assembly 236 relative to the first filter cabinet 200 and using the first supplemental filter support assembly 236 to support at least some of the set of supplemental filters.

FIG. 2E illustrates addition of the set of supplemental filters relative to the first filter cabinet 200, according to some embodiments. In some embodiments, the set of supplemental filters comprises a fifth supplemental filter 256 in the first filter location 252 (shown in FIG. 2D), a sixth supplemental filter 258 in the second filter location 254 and the one or more first supplemental filters comprising the first supplemental filter 242, the second supplemental filter 244, the third supplemental filter 246 and the fourth supplemental filter 248, wherein the one or more first supplemental filters are supported by the first supplemental filter support assembly 236. In some embodiments, the first supplemental filter support assembly 236 is installed relative to the first filter cabinet 200, and subsequent to installing the first supplemental filter support assembly 236, the one or more first supplemental filters are situated relative to the first supplemental filter support assembly 236 such that the one or more first supplemental filters are supported by the first supplemental filter support assembly 236.

In some embodiments, each filter of one, some, or all of the set of supplemental filters comprises a respective type 1 filter. In some embodiments, the set of supplemental filters are added relative to the first filter cabinet 200 to retrofit the type 1 filter to the fluid filtration system 100. In some embodiments, each filter of one, some, or all of the set of supplemental filters is a type 1 filter being added to a fluid filtering pipeline, of a set of fluid filtering pipelines, for filtering fluid and/or supplying filtered fluid to a semiconductor processing station. In some embodiments, each fluid filtering pipeline of the set of fluid filtering pipelines supplies filtered fluid to a respective processing station of a set of processing stations. In some embodiments, the set of supplemental filters comprise at least one of (i) the first (type 1) filter 106 (shown in FIG. 1A) added to a first fluid pipeline (comprising the first filter 106 and the second filter 122) for filtering fluid for supply to the first semiconductor processing station 150, (ii) a second type 1 filter added to a second fluid pipeline for filtering fluid for supply to the second semiconductor processing station, (iii) a third type 1 filter added to a third fluid pipeline for filtering fluid for supply to a third semiconductor processing station, etc.

In some embodiments, each filter of one, some, or all filters arranged relative to the first filter cabinet 200 is connected to at least one of another filter or a semiconductor processing station via one or more conduits (not shown). For simplicity, conduits and/or other components used to conduct fluid through filters of the first filter cabinet 200 and/or to semiconductor processing stations are not illustrated in FIGS. 2A-2F and FIGS. 2G-2H. In some embodiments, at least some of the components shown in FIG. 1A, such as the first filter 106, the second filter 122, the drain manifold 116, etc., are arranged relative to the first filter cabinet 200 and/or disposed in the filter cabinet space 212. In some embodiments, the first filter 106 (shown in FIG. 1A) is comprised within at least one of (i) the one or more first supplemental filters supported by the first supplemental filter support assembly 236, or (ii) the first plurality of filters supported by the first filter support assembly 220. In some embodiments, the second filter 122 (shown in FIG. 1A) is comprised within at least one of (i) the one or more first supplemental filters supported by the first supplemental filter support assembly 236, or (ii) the first plurality of filters supported by the first filter support assembly 220.

FIGS. 2F-2H illustrate enlarged views of the first supplemental filter support assembly 236, according to some embodiments. FIG. 2F illustrates the first supplemental filter support assembly 236 without filters, according to some embodiments. In some embodiments, the first support beam 232 is moveable in a first direction 268 (shown in FIGS. 2A and 2F) and a second direction 270 (shown in FIGS. 2A and 2F). In some embodiments, the first supplemental filter support assembly 236 comprises at least one of a first support beam displacement mechanism 264 or a second support beam displacement mechanism 266. In some embodiments, the first support beam 232 is moveably coupled to at least one of the first support beam displacement mechanism 264 or the second support beam displacement mechanism 266. In some embodiments, at least one of the first support beam displacement mechanism 264 or the second support beam displacement mechanism 266 enables the first support beam to be moved in the first direction 268 and the second direction 270. In some embodiments, at least one of the first support beam displacement mechanism 264 or the second support beam displacement mechanism 266 allows the first support beam to slide in the first direction 268 and the second direction 270, such as in a drawer-like manner. In some embodiments, at least one of the first support beam displacement mechanism 264 defines a first groove 260 or the second support beam displacement mechanism 266 defines a second groove 262. In some embodiments, the first support beam 232 comprises a first protrusion (not shown) in the first groove 260 and a second protrusion (not shown) in the second groove 262. In some embodiments, the first protrusion travels along the first groove 260 and/or the second protrusion travels along the second groove 262 when the first support beam 232 is displaced in the first direction 268 or the second direction 270. In some embodiments, the first supplemental filter support assembly 236 comprises one or more position locking components for locking and/or tightening the first support beam 232 to a desired position. In some embodiments, the one or more position locking components comprise at least one of a first locking component 278, a second locking component 280, a third locking component 272, or a fourth locking component 274. In some embodiments, at least one of the first locking component 278 comprises a first bracket lock, the second locking component 280 comprises a second bracket lock, the third locking component 272 comprises a third bracket lock, or the fourth locking component 274 comprises a fourth bracket lock. In some embodiments, the first locking component 278 is attached, such as using one or more screws, to the first support beam 232 and the first support beam displacement mechanism 264 to lock and/or tighten the first support beam 232 into the desired position. In some embodiments, the second locking component 280 is attached, such as using one or more screws, to the first support beam 232 and the first support beam displacement mechanism 264 to lock and/or tighten the first support beam 232 into the desired position. In some embodiments, the third locking component 272 is attached, such as using one or more screws, to the first support beam 232 and the second support beam displacement mechanism 266 to lock and/or tighten the first support beam 232 into the desired position. In some embodiments, the fourth locking component 274 is attached, such as using one or more screws, to the first support beam 232 and the second support beam displacement mechanism 266 to lock and/or tighten the first support beam 232 into the desired position. In some embodiments, at least one of the first locking component 278, the second locking component 280, the third locking component 272, or the fourth locking component 274 is detached and/or loosened from the first support beam 232, such as by removing one or more screws, to allow the first support beam 232 to be moved to a different position.

FIG. 2G illustrates the first supplemental filter support assembly 236 supporting supplemental filters 282, 284 and 286, according to some embodiments. In some embodiments, each filter of one, some, or all filters supported by the first supplemental filter support assembly 236 is connected to a set of conduits. In some embodiments, the supplemental filter 282 is connected to at least one of a first conduit 288, a second conduit 290, or a third conduit 292. In some embodiments, at least one of the first conduit 288 is connected to an input port of the supplemental filter 282, the second conduit 290 is connected to an output port of the supplemental filter 282, or the third conduit 292 is connected to a vent port of the supplemental filter 282. In some embodiments, the supplemental filter 282 is attached to a first filter coupling device 294, which is at least one of supported by or hanging from the first support beam 232. In some embodiments, the supplemental filter 284 is attached to a second filter coupling device 296, which is at least one of supported by or hanging from the first support beam 232. In some embodiments, the supplemental filter 286 is attached to a third filter coupling device 298, which is at least one of supported by or hanging from the first support beam 232.

In some embodiments, the first support beam 232 is moved in the second direction 270 from a first position shown in FIG. 2G to a second position (not shown). In some embodiments, the first support beam 232 is moved from the first position to the second position to facilitate access to one or more third components at least one of the first filter support assembly 220, a filter of the first plurality of filters supported by the first filter support assembly 220, one or more components in the filter cabinet space 212, or one or more other components. In some embodiments, when the first support beam 232 has the first position, a maintenance operator, such as a human, a robot, etc., is unable to access the one or more third components, such as due, at least in part, to the first support beam 232 and/or filters supported by the first support beam 232 obstructing the maintenance operator's access to the one or more third components. In some embodiments, when the first support beam 232 has the second position, the maintenance operator is able to access the one or more third components and/or perform a maintenance operation in association with a component of the one or more third components.

Embodiments are contemplated in which multiple rows of supplemental filters are established in the filter cabinet space 212. FIG. 2H illustrates the first filter cabinet 200 with multiple rows of supplemental filters, according to some embodiments. In some embodiments, a first row of supplemental filters comprises the first supplemental filter 242, the second supplemental filter 244, the third supplemental filter 246 and the fourth supplemental filter 248, and a second row of supplemental filters over the first row of supplemental filters comprises a seventh supplemental filter 213, an eighth supplemental filter 215, and a ninth supplemental filter 217. In some embodiments, the second row of supplemental filters is supported using a sixth supplemental filter support assembly 205, such as using one or more of the techniques provided herein with respect to the first supplemental filter support assembly 236. In some embodiments, the sixth supplemental filter support assembly 205 has one or more of the features, dimensions, interrelationships with other elements, etc. provided herein with respect to the first supplemental filter support assembly 236.

In some embodiments, the sixth supplemental filter support assembly 205 comprises a second support beam 207 configured to support the second row of supplemental filters. In some embodiments, the sixth supplemental filter support assembly 205 comprises at least one of a third support post 211 or a fourth support post 209. In some embodiments, the second support beam 207 is at least one of coupled to or supported by at least one of the third support post 211 or the fourth support post 209. In some embodiments, the third support post 211 is coupled to at least one of the second wall 208, the floor 206, the first supplemental filter support assembly 236, or other structure. In some embodiments, the fourth support post 209 is coupled to at least one of the first wall 204, the floor 206, the first supplemental filter support assembly 236, or other structure. In some embodiments, at least one of the second support beam 207, the third support post 211, or the fourth support post 209 comprises at least one of one or more brackets or other suitable structures.

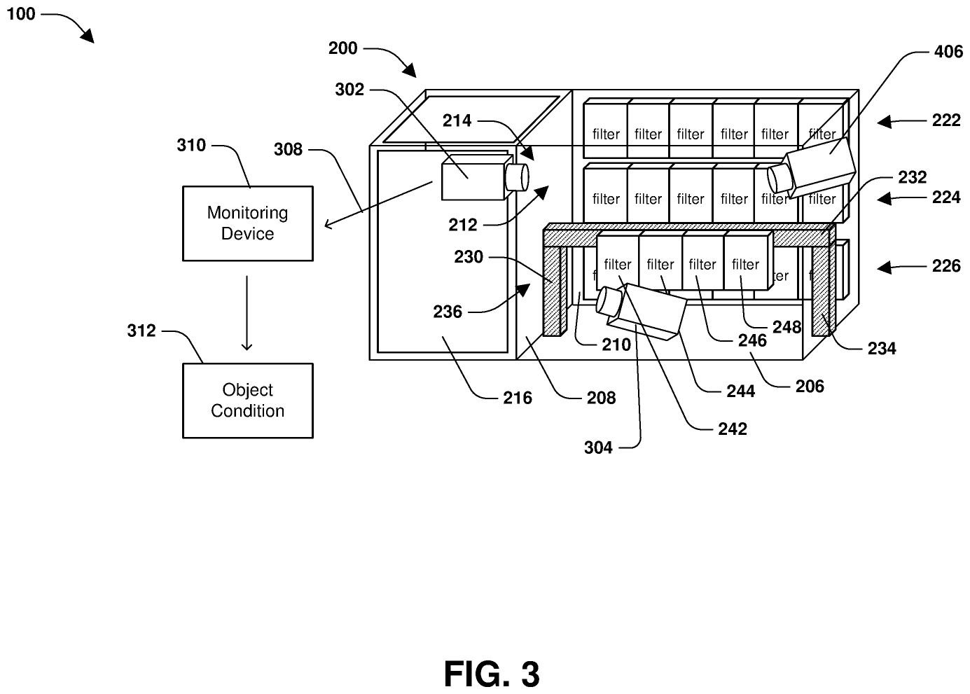

FIG. 3 illustrates aspects of the fluid filtration system 100, in accordance with some embodiments. In some embodiments, the fluid filtration system 100 comprises at least one of a monitoring device 310 or one or more cameras. The one or more cameras comprise at least one of a first camera 302, a second camera 304, a third camera 306, or one or more other cameras. In some embodiments, the one or more cameras capture images comprising views of one or more fourth components. In some embodiments, the one or more fourth components comprise at least one of (i) one or more filters of the first plurality of filters, (ii) one or more filters of the one or more first supplemental filters positioned relative to the first supplemental filter support assembly 236, such as at least one of the first supplemental filter 242, the second supplemental filter 244, the third supplemental filter 246, the fourth supplemental filter 248, or one or more other supplemental filters, (iii) one or more conduits used to conduct fluid to and/or from a filter disposed in the filter cabinet space 212, such as at least one of the first conduit 288, the second conduit 290, the third conduit 292 (shown in FIG. 2G), or one or more of the conduits shown in FIG. 1A, (iv) one or more conduits used to conduct filtered fluid to a semiconductor processing station, such as the conduit 152 shown in FIG. 1B, (v) at least a portion of the first supplemental filter support assembly 236, such as at least one of the first support beam 232, the first support post 230, the second support post 234, the first support beam displacement mechanism 264, the second support beam displacement mechanism 266, or one or more other components of the first supplemental filter support assembly 236, (vi) at least a portion of the first filter support assembly 220, (vii) one or more filtering coupling devices used for supporting one or more filters disposed in the filter cabinet space 212, such as at least one of the first filter coupling device 294, the second filter coupling device 296, or the third filter coupling device 298 (shown in FIG. 2G), (viii) one or components, such as structural components, of the first filter cabinet 200, or (ix) one or more other suitable components.

In some embodiments, the one or more cameras transmit one or more images 308 to the monitoring device 310. In some embodiments, the one or more cameras transmit the one or more images 308 wirelessly, such as using a wireless communication device. In some embodiments, the one or more cameras transmit the one or more images 308 over a physical connection. In some embodiments, the monitoring device 310 comprises a processor, such as an image processor, to analyze a first image of the one or more images 308 to determine a condition 312 of a first object depicted in the first image. In some embodiments, the first object comprises at least a portion of a component of the one or more fourth components. In some embodiments, the first object is a metal object. In some embodiments, the condition is indicative of an internal stress of the first object. In some embodiments, the internal stress corresponds to a measure of residual stress in the first object. In some embodiments, the first image comprises an X-ray image or other suitable type of image. In some embodiments, the one or more cameras comprise at least one of one or more X-ray cameras or one or more other suitable types of cameras. In some embodiments, at least one of the monitoring device 310 or the one or more cameras comprises an X-ray residual stress analyzer used to determine the internal stress of the first object. In some embodiments, the X-ray residual stress analyzer comprises the processor.

In some embodiments, the processor is configured to initiate a first maintenance operation in response to determining that the internal stress is greater than a threshold internal stress. In some embodiments, the processor transmits a maintenance operation initiation message to a maintenance system. In some embodiments, in response to the maintenance operation initiation message, the maintenance system allocates one or more resources for the first maintenance operation. In some embodiments, the first maintenance operation comprises at least one of repairing the first object, replacing the first object with a replacement object, flushing a filter comprised within the first object, servicing a filter comprised within the first object, or other suitable operation. In some embodiments, the internal stress of the first object being greater than the threshold internal stress is indicative of a filter (that is at least one of coupled to the first object or comprised within the first object) needing to be at least one of flushed, repaired, serviced, or replaced. In some embodiments, the first maintenance operation comprises at least one of repositioning the filter, flushing the filter, repairing the filter, servicing the filter, or replacing the filter.

In some embodiments, the condition is indicative of a maintenance priority level. In some embodiments, the maintenance priority level is selected from among various priority levels, such as at least one of low priority level, average priority level, critical priority level, etc. In some embodiments, at least one of the maintenance priority level is low priority level when the internal stress is within a first range, the maintenance priority level is average priority level when the internal stress is within a second range greater than the first range, or the maintenance priority level is critical priority level when the internal stress is at least one of greater than an upper limit of the second range or within a third range greater than the second range. In some embodiments, the maintenance system allocates resources for the first maintenance operation based upon the maintenance priority level. In some embodiments, the maintenance system provides instructions to a maintenance operator to perform the first maintenance operation more quickly when the maintenance priority level is critical priority level as compared to when the maintenance priority level is low priority level or average priority level. In some embodiments, the monitoring device 310 processes images received from the one or more cameras monitor the internal stress of the first object and/or update the maintenance priority level, such as modify the maintenance priority level from average priority level to critical priority level in response to the internal stress reaching and/or being greater than the upper limit of the second range.

In some embodiments, a wafer monitoring system monitors semiconductor wafers processed by a semiconductor processing station using filtered fluid supplied by a fluid filtering pipeline of the fluid filtration system 100. In some embodiments, the wafer monitoring system analyzes images of the semiconductor wafers, such as using image processing techniques and/or other techniques, to check for defects in the semiconductor wafers. In some embodiments, the defects comprise at least one of metal defects, such as metal cones and/or metal residue, or one or other types of defects. In some embodiments, based upon a determination that a measure of defects in the semiconductor wafers is greater than a threshold measure of defects, the wafer monitoring system determines that a filter, such as a type 1 filter, in the fluid filtering pipeline needs to be at least one of flushed, repaired, serviced, or replaced. In some embodiments, in response to determining that the measure of defects in the semiconductor wafers is greater than the threshold measure of defects, the wafer monitoring system initiates a second maintenance operation comprising at least one of repositioning the filter, flushing the filter, repairing the filter, servicing the filter, or replacing the filter. In some embodiments, the second maintenance operation is performed using one or more of the techniques provided herein with respect to the first maintenance operation.

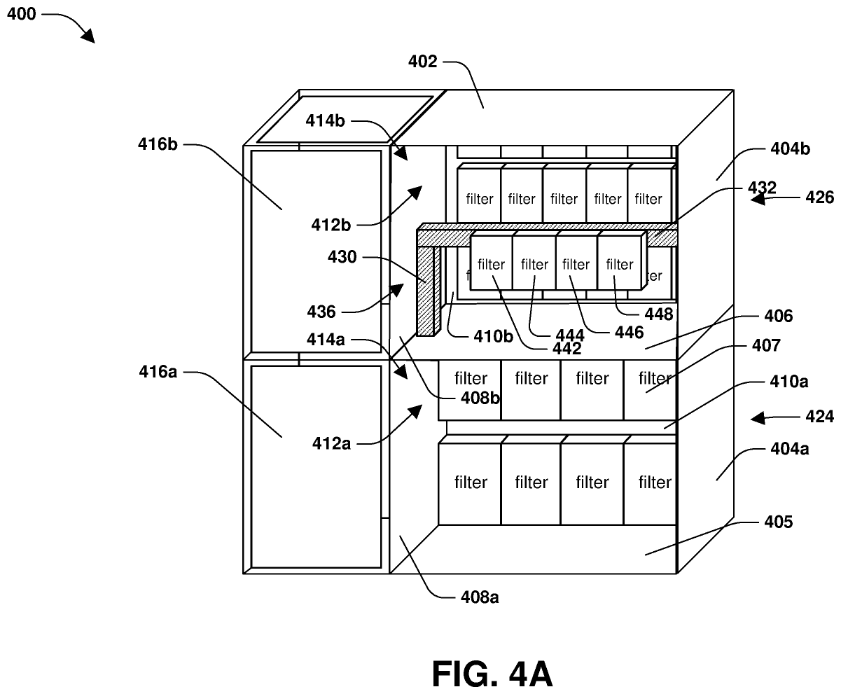

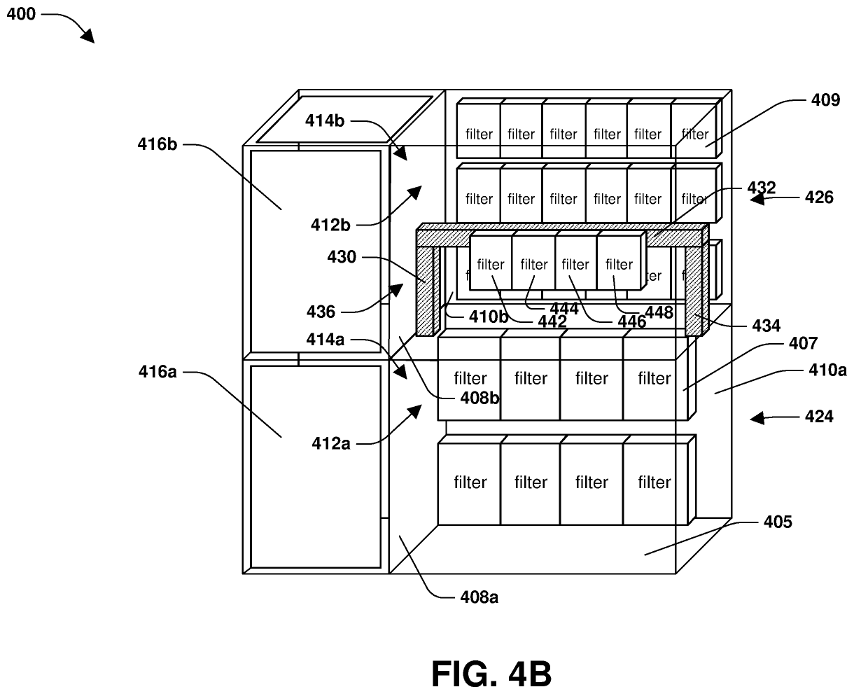

FIGS. 4A-4B illustrate aspects of a second filter cabinet 400 of the fluid filtration system 100, according to some embodiments. FIG. 4A illustrates a perspective view of the second filter cabinet 400, according to some embodiments. In some embodiments, the second filter cabinet 400 has one or more of the features, dimensions, interrelationships with other elements, etc. provided herein with respect to the first filter cabinet 200. In some embodiments, the second filter cabinet 400 is a multi-level cabinet comprising a first level 424 and a second level 426 over the first level 424. In some embodiments, the first level 424 has one or more of the features, dimensions, interrelationships with other elements, etc. provided herein with respect to the first filter cabinet 200. In some embodiments, the second level 426 has one or more of the features, dimensions, interrelationships with other elements, etc. provided herein with respect to the first filter cabinet 200. In some embodiments, the second filter cabinet 400 comprises at least one of a floor 405, a ceiling 402, a separator 406, or one or more walls to define at least one of a second filter cabinet space 412a of the first level 424 or a third filter cabinet space 412b of the second level 426. In some embodiments, the separator 406 separates the first level 424 from the second level 426. In some embodiments, the separator 406 at least one of acts as a floor for the second level 426 or acts as a ceiling for the first level 424. In some embodiments, the one or more walls comprise at least one of a wall 404a, a wall 408a opposing the wall 404a, or a wall 410a. In some embodiments, the wall 410a opposes a second opening 414a to the second filter cabinet space 412a. In some embodiments, the second filter cabinet 400 comprises a first door (not shown), fitted to the second opening 414a, to provide ingress and egress to the second filter cabinet space 412a. In some embodiments, when the first door is open, the second filter cabinet space 412a is exposed by the second opening 414a to allow one or more maintenance operations to be performed. In some embodiments, the one or more walls comprise at least one of a wall 404b, a wall 408b opposing the wall 404b, or a wall 410b. In some embodiments, the wall 410b opposes a third opening 414b to the third filter cabinet space 412b. In some embodiments, the second filter cabinet 400 comprises a second door (not shown), fitted to the third opening 414b, to provide ingress and egress to the third filter cabinet space 412b. In some embodiments, when the second door is open, the third filter cabinet space 412b is exposed by the third opening 414b to allow one or more maintenance operations to be performed.

In some embodiments, the second filter cabinet 400 comprises at least one of a first enclosure 416a of the first level 424 or a second enclosure 416b of the second level 426 over the first enclosure 416a. In some embodiments, one or more components (not shown) of the fluid filtration system 100 are disposed in at least one of the first enclosure 416a or the second enclosure 416b.

In some embodiments, the second filter cabinet 400 comprises a second filter support assembly (not shown), in the second filter cabinet space 412a, configured to support a second plurality of filters comprising a filter 407 (shown in FIG. 4A and 4B) and other filters. In some embodiments, the second filter cabinet 400 comprises a third filter support assembly (not shown), in the third filter cabinet space 412b, configured to support a third plurality of filters comprising a filter 409 (shown in FIG. 4B) and other filters. At least one of the second filter support assembly or the third filter support assembly comprises at least one of one or more metals or one or more other suitable materials. In some embodiments, at least one of the second filter support assembly or the third filter support assembly has one or more of the features, dimensions, interrelationships with other elements, etc. provided herein with respect to the first filter support assembly 220 (shown in FIG. 2B). In some embodiments, the second filter support assembly is at least one of proximal to, coupled to, or in contact with the wall 410a. In some embodiments, the third filter support assembly is at least one of proximal to, coupled to, or in contact with the wall 410b. In some embodiments, the second filter support assembly comprises at least one of one or more shelving units, one or more support beams, one or more brackets, or one or more other types of structures to support the second plurality of filters. In some embodiments, the third filter support assembly comprises at least one of one or more shelving units, one or more support beams, one or more brackets, or one or more other types of structures to support the third plurality of filters.

Embodiments are contemplated in which the second filter cabinet 400 does not comprise at least one of the floor 405, the ceiling 402, the separator 406, the wall 404a, the wall 408a, the wall 410a, the wall 404b, the wall 408b, or the wall 410b. FIG. 4B illustrates the second filter cabinet 400 according to some embodiments in which the second filter cabinet 400 does not comprise at least one of the ceiling 402, the separator 406, the wall 404a, or the wall 404b. For simplicity, the second filter support assembly and the third filter support assembly are not illustrated in FIG. 4B.

In some embodiments, the second filter cabinet 400 comprises a second supplemental filter support assembly 436, in the third filter cabinet space 412b, configured to support one or more second supplemental filters. The second supplemental filter support assembly 436 comprises at least one of one or more metals or one or more other suitable materials. In some embodiments, the second supplemental filter support assembly 436 is between the third filter support assembly and the third opening 414b. In some embodiments, the second supplemental filter support assembly 436 is between the first filter support assembly 220 and the third opening 414b. In some embodiments, the second supplemental filter support assembly 436 is between the first plurality of filters and the third opening 414b. In some embodiments, the one or more second supplemental filters comprise at least one of a supplemental filter 442, a supplemental filter 444, a supplemental filter 446, a supplemental filter 448, or one or more other supplemental filters. In some embodiments, the second supplemental filter support assembly 436 comprises a support beam 432 configured to support the one or more second supplemental filters. In some embodiments, the second supplemental filter support assembly 436 comprises at least one of a support post 430 or a support post 434. In some embodiments, the support beam 432 is at least one of coupled to or supported by at least one of the support post 430 or the support post 434. In some embodiments, at least one of the support beam 432, the support post 430, or the support post 434 comprises at least one of one or more brackets or other suitable structures.

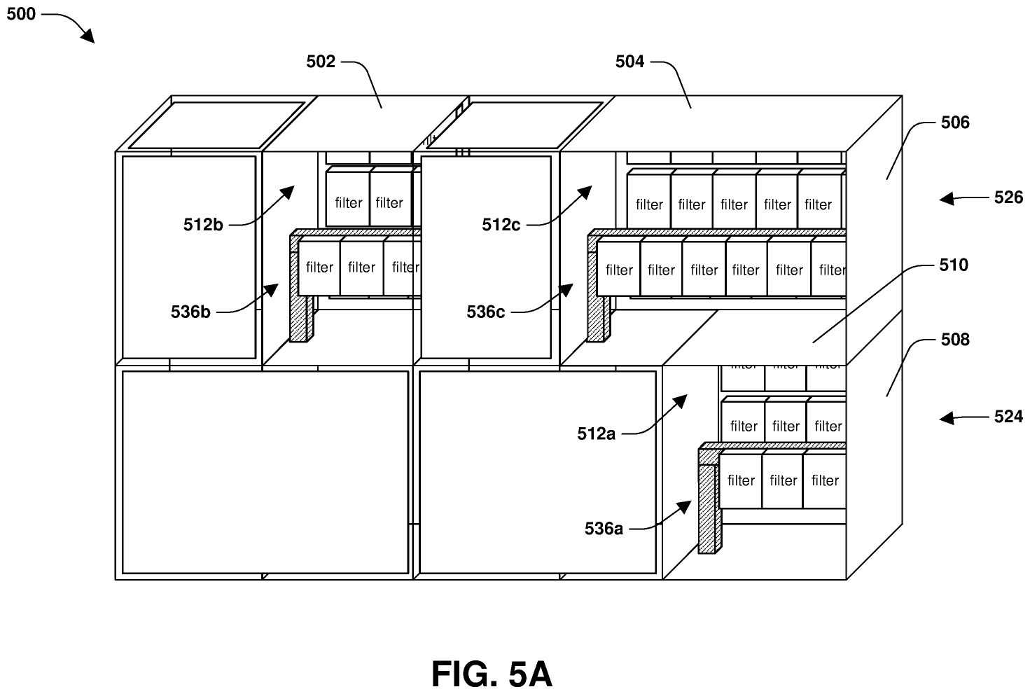

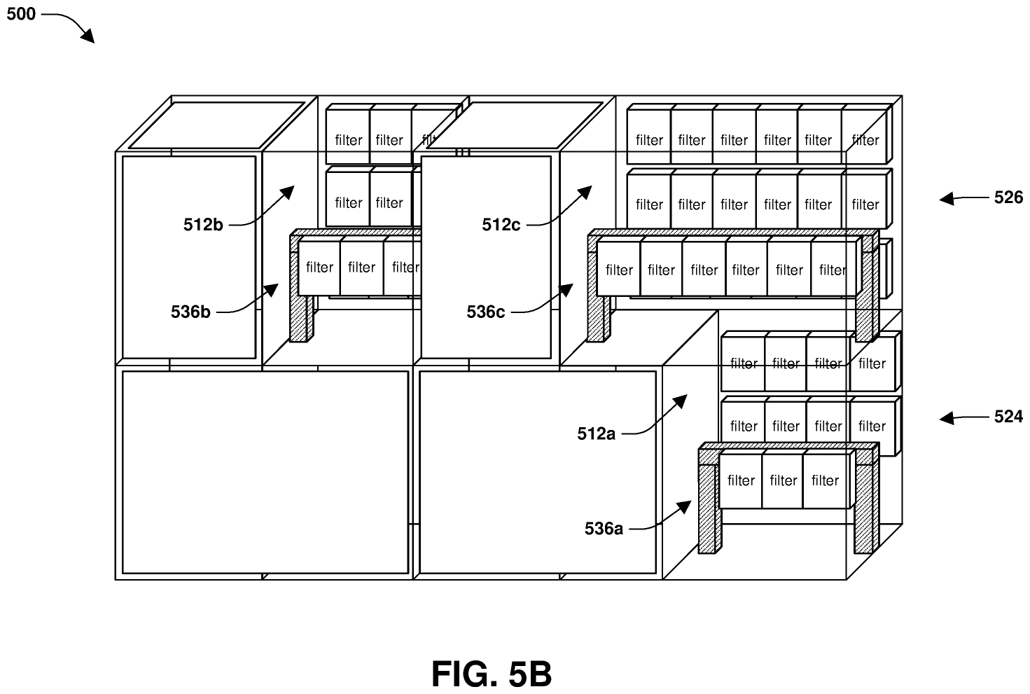

In some embodiments, the fluid filtration system 100 comprises a filter cabinet defining multiple cabinet filter spaces in a single level. FIGS. 5A-5B illustrate aspects of a third filter cabinet 500 of the fluid filtration system 100, according to some embodiments. FIG. 5A illustrates a perspective view of the third filter cabinet 500, according to some embodiments. In some embodiments, the third filter cabinet 500 has one or more of the features, dimensions, interrelationships with other elements, etc. provided herein with respect to at least one of the first filter cabinet 200 or the second filter cabinet 400. In some embodiments, the third filter cabinet 500 is a multi-level cabinet comprising a first level 524 and a second level 526 over the first level 524. In some embodiments, the first level 524 has one or more of the features, dimensions, interrelationships with other elements, etc. provided herein with respect to the first filter cabinet 200. In some embodiments, the second level 526 has one or more of the features, dimensions, interrelationships with other elements, etc. provided herein with respect to the first filter cabinet 200.

In some embodiments, the third filter cabinet 500 comprises at least one of one or more walls, one or more separators, one or more ceilings, one or more floors, etc. to define at least one of a fourth filter cabinet space 512a in the first level 524, a fifth filter cabinet space 512b in the second level 526, or a sixth filter cabinet space 512c in the second level 526. In some embodiments, the third filter cabinet 500 comprises one or more supplemental filter support assemblies comprising at least one of a third supplemental filter support assembly 536a in the fourth filter cabinet space 512a, a fourth supplemental filter support assembly 536b in the fifth filter cabinet space 512b, or a fifth supplemental filter support assembly 536c in the sixth filter cabinet space 512c. In some embodiments, each supplemental filter support assembly of the one or more supplemental filter support assemblies has one or more of the features, dimensions, interrelationships with other elements, etc. provided herein with respect to at least one of the first supplemental filter support assembly 236 or the second supplemental filter support assembly 436. In some embodiments, each supplemental filter support assembly of the one or more supplemental filter support assemblies is used to support one or more supplemental filters. FIG. 5B illustrates the third filter cabinet 500 according to some embodiments in which the third filter cabinet 500 does not comprise at least one of a first ceiling 502 (shown in FIG. 5A), a second ceiling 504 (shown in FIG. 5A), a wall 506 (shown in FIG. 5A), a wall 508 (shown in FIG. 5A), or a separator 510 (shown in FIG. 5A).

In some embodiments, a fluid filtration system for a semiconductor processing station is provided. The fluid filtration system includes a filter cabinet. The filter cabinet includes one or more walls to define a filter cabinet space. The filter cabinet includes a filter support assembly, in the filter cabinet space, configured to support a first plurality of filters. The filter cabinet includes a supplemental filter support assembly, in the filter cabinet space, configured to support one or more supplemental filters. The supplemental filter support assembly is between the filter support assembly and an opening to the filter cabinet space. The fluid filtration system includes a conduit configured to conduct first filtered fluid from the filter cabinet to the semiconductor processing station. The first filtered fluid is filtered using a first filter of the one or more supplemental filters.

In some embodiments, a fluid filtration system for a semiconductor processing station is provided. The fluid filtration system includes a first filter configured to filter metal ions from a first fluid to produce a first filtered fluid. The fluid filtration system includes a second filter configured to filter particles from the first filtered fluid to produce a second filtered fluid. The fluid filtration system includes a conduit configured to conduct the second filtered fluid to the semiconductor processing station.

In some embodiments, a fluid filtration system for a semiconductor processing station is provided. The fluid filtration system includes a first filter configured to filter particles from a first fluid to produce a first filtered fluid. The fluid filtration system includes a second filter configured to filter metal ions from the first filtered fluid to produce a second filtered fluid. The fluid filtration system includes a conduit configured to conduct the second filtered fluid to the semiconductor processing station.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A fluid filtration system for a semiconductor processing station, comprising:
a filter cabinet comprising:
one or more walls to define a filter cabinet space;
a filter support assembly, in the filter cabinet space, configured to support a first plurality of filters; and
a supplemental filter support assembly, in the filter cabinet space, configured to support one or more supplemental filters, wherein the supplemental filter support assembly is between the filter support assembly and an opening to the filter cabinet space; and
a conduit configured to conduct first filtered fluid from the filter cabinet to the semiconductor processing station, wherein the first filtered fluid is filtered using a first filter of the one or more supplemental filters.

2. The fluid filtration system of claim 1, wherein:
the first filter is configured to filter metal ions from a first fluid to produce the first filtered fluid.

3. The fluid filtration system of claim 1, wherein:
the first filtered fluid is filtered using a second filter of the first plurality of filters.

4. The fluid filtration system of claim 1, wherein:
the supplemental filter support assembly comprises a moveable support beam configured to move from a first position to a second position to facilitate access to at least one of:
the filter support assembly; or
a filter of the first plurality of filters.

5. The fluid filtration system of claim 1, comprising:
a camera configured to capture an image of an object comprising at least one of:
a first component of the filter support assembly;
a filter of the first plurality of filters;
a second component of the supplemental filter support assembly;
a supplemental filter of the one or more supplemental filters; or the conduit; and
a processor configured to determine a condition of the object based upon the image.

6. The fluid filtration system of claim 5, wherein:
the condition is indicative of an internal stress of the object; and
the processor is configured to initiate a maintenance operation in response to determining that the internal stress is greater than a threshold internal stress.

7. The fluid filtration system of claim 5, wherein:
the image comprises an X-ray image.

8. The fluid filtration system of claim 1, wherein:
the semiconductor processing station is configured to dispense the first filtered fluid onto a semiconductor wafer.

9. The fluid filtration system of claim 1, wherein:
the first filtered fluid comprises a developer.

10. The fluid filtration system of claim 1, wherein:
the semiconductor processing station is configured to dispense the first filtered fluid onto a photoresist to develop a photomask.

11. The fluid filtration system of claim 1, wherein:
the first filter comprises a chelating agent that combines with a metal ion in a fluid to form a metal chelate; and
the metal chelate is filtered from the fluid to produce the first filtered fluid.

12. A fluid filtration system for a semiconductor processing station, comprising:
a first filter configured to filter metal ions from a first fluid to produce a first filtered fluid;
a second filter configured to filter particles from the first filtered fluid to produce a second filtered fluid; and
a conduit configured to conduct the second filtered fluid to the semiconductor processing station.

13. The fluid filtration system of claim 12, wherein:
the semiconductor processing station is configured to dispense the second filtered fluid onto a semiconductor wafer.

14. The fluid filtration system of claim 12, wherein:
the second filtered fluid comprises a developer.

15. The fluid filtration system of claim 12, wherein:
the semiconductor processing station is configured to dispense the second filtered fluid onto a photoresist to develop a photomask.

16. The fluid filtration system of claim 12, wherein:
the first filter comprises a chelating agent that combines with a metal ion to form a metal chelate; and
the metal chelate is filtered from the first fluid to produce the first filtered fluid.

17. A fluid filtration system for a semiconductor processing station, comprising:
a first filter configured to filter particles from a first fluid to produce a first filtered fluid;
a second filter configured to filter metal ions from the first filtered fluid to produce a second filtered fluid; and
a conduit configured to conduct the second filtered fluid to the semiconductor processing station.

18. The fluid filtration system of claim 17, wherein:
the semiconductor processing station is configured to dispense the second filtered fluid onto a semiconductor wafer.

19. The fluid filtration system of claim 17, wherein:
the second filtered fluid comprises a developer.

20. The fluid filtration system of claim 17, wherein:
the semiconductor processing station is configured to dispense the second filtered fluid onto a photoresist to develop a photomask.
